(19) United States
(12) Patent Application Publication
(10) Pub. No.: US 2011/0061735 A1
(43) Pub. Date: Mar. 17, 2011

(54) CROSSLINKABLE ETHYLENE COPOLYMER COMPOSITION, ENCAPSULATING SHEET FOR SOLAR CELL ELEMENT COMPOSED OF THE SAME, AND SOLAR CELL MODULE USING THE SHEET

(75) Inventor: Koichi Nishijima, Chiba (JP)

(73) Assignee: DU PONT-MITSUI POLYCHEMICALS CO., LTD., Tokyo (JP)

(21) Appl. No.: 12/992,116

(22) PCT Filed: May 12, 2008
(86) PCT No.: PCT/JP2008/058708

§ 371 Date: Nov. 11, 2010

(51) Int. Cl. H01L 31/02; C08F 4/16; C08L 23/08

(52) U.S. Cl. 136/259; 526/194; 523/134

(57) ABSTRACT

The present invention provides a crosslinkable ethylene copolymer composition which is superior in transparency, heat resistance, adhesive property, flexibility, moldability, durability, and the like, as well as in insulating property, and which shows less decrease in adhesive property with time and can maintain the adhesive property for a long period, and a crosslinkable sheet composed of said composition, and an encapsulating sheet for solar cell and a solar cell module. More in detail, the present invention relates to a crosslinkable ethylene copolymer composition comprising a dialkoxysilane having a double bond in a ratio of 3 parts by weight or less to 100 parts by weight of ethylene copolymer, and a crosslinked sheet of said composition, and further to an encapsulating sheet for solar cell composed of said composition and a solar cell module using the sheet.

### TECHNICAL FIELD

The present invention relates to a crosslinkable ethylene copolymer composition suitable for encapsulating a solar cell to fix a solar cell element in a solar cell module, an encapsulating sheet composed of said ethylene copolymer composition, and a solar cell module encapsulated a solar cell element by said sheet. More in detail, the present invention relates to a crosslinkable ethylene copolymer composition which is superior in transparency, flexibility, processability, adhesive property, crosslinking property as well as superior in insulating property, an encapsulating sheet composed of said ethylene copolymer composition, and a solar cell module encapsulated a solar cell element by said sheet.

### BACKGROUND ART

Hydraulic power generation, wind force power generation, photovoltaic generation, and the like which utilize inexhaustible natural energy and capable of improving reduction of carbon dioxide and other environmental issues are attracting attentions. Among these, the photovoltaic generation has shown a remarkable progress in its prevalence in recent years, because as well as improvements in performance such as power generation efficiency of solar cell module are remarkable, lowering of prices has been progressed, and promotion programs for introducing residential photovoltaic generation system by the government or local governments have been pursued.

In the photovoltaic generation, the sunlight energy is directly converted to electric energy, where since performance of the solar cell element deteriorates by directly contacting with the ambient air, the solar cell element is interleaved with a encapsulating material to provide buffering as well as to prevent commingling of foreign materials or invasion by moisture and the like. For this encapsulating material, the following various performances are required: that is, the material must be transparent not to inhibit power generation by light, should not leak out or collapse by heat (heat resistance), should have a good adhesion to glass or back sheet of a protective material, should not generate remarkable deterioration or yellowing by sunlight, and the like, and in order to fulfill these requirements, various compounding formulations have been studied. For example, as a representative formulations considering transparency, heat resistance, adhesive property, flexibility, moldability, durability, and the like, it is known that a composition comprising an ethylene-vinyl acetate copolymer, a peroxide, and a silane coupling agent is used as a encapsulating material for solar cell (see, for example, Patent Literature 1).

Such crosslinkable ethylene copolymer composition is sometimes forced to experience a long period of inventory time, due to production schedule and production adjustment in the module manufacturer. In such case, the encapsulating materials conventionally proposed have had a risk that physical properties thereof may vary with time by any means. In particular, adhesive property has had a fear that it decreases with time. Thus, a technology by which physical properties do not vary even after a long period of inventory time has been demanded for many years.

The inventors of the present invention have studied about a development of a crosslinkable ethylene copolymer composition which shows less decrease in adhesive property with time while superior performances of the crosslinkable ethylene copolymer composition proposed by the applicant of the present invention are maintained, and accomplished the present invention.

[Patent Literature 1]: JP-B-62-14111

[Patent Literature 2]: JP-A-2006-36875

### DISCLOSURE OF THE INVENTION

### Problem to be Solved by the Invention

It is an object of the present invention to provide a crosslinkable ethylene copolymer composition which is superior in transparency, heat resistance, adhesive property, flexibility, moldability, durability, and the like, as well as in insulating property, and which shows less decrease in adhesive property with time and can maintain the adhesive property for a long period, and a crosslinkable sheet composed of said composition.

It is also another object of the present invention to provide a crosslinkable ethylene copolymer composition having the aforementioned features suitable for encapsulating a solar cell.

It is also another object of the present invention to provide a crosslinkable sheet of the crosslinkable ethylene copolymer composition, and an encapsulating sheet for solar cell and a solar cell module using the same.

### Means for Solving the Problem

The present invention provides a crosslinkable ethylene copolymer composition comprising a dialkoxysilane having a double bond in an amount of 3 parts by weight or less to 100 parts by weight of an ethylene copolymer.

The present invention also provides the aforementioned crosslinkable ethylene copolymer composition comprising a peroxide having one-hour half-life temperature of 140° C. or lower.

The aforementioned crosslinkable ethylene copolymer composition further comprising a crosslinking auxiliary agent containing an allyl group is a preferable embodiment of the present invention.

The aforementioned crosslinkable ethylene copolymer composition further comprising a weathering stabilizer additive selected from UV-absorbing agent, hindered amine, and antioxidant is a preferable embodiment of the present invention.

The present invention provides a crosslinkable ethylene copolymer composition for encapsulating the solar cell element composed of the aforementioned crosslinkable ethylene copolymer composition.

The present invention also provides a crosslinkable sheet composed of the aforementioned crosslinkable ethylene copolymer composition, in particular, a crosslinkable sheet for encapsulating the solar cell element.

The present invention further provides a encapsulating sheet for solar cell element obtainable by crosslinking the aforementioned crosslinkable ethylene copolymer composition or a sheet thereof, and a solar cell module using the same.

### Effect of the Invention

According to the present invention, a crosslinkable ethylene copolymer composition which is superior in transparency, heat resistance, adhesive property, flexibility, moldability, durability, and the like, as well as in insulating property, and which shows superior insulating property and less decrease in adhesive property with time can be provided.

According to the present invention, a crosslinkable ethylene copolymer composition for encapsulating solar cell composed of a crosslinkable ethylene copolymer composition having superior performances can be provided.

According to the present invention, a crosslinked sheet of a crosslinkable ethylene copolymer composition having superior performance, an encapsulating sheet for solar cell and a solar cell module using the same can be also provided.

### Best Mode for Carrying Out the Invention

The crosslinkable ethylene copolymer composition provided by the present invention is the one comprising a dialkoxysilane having a double bond in an amount of 3 parts by weight or less to 100 parts by weight of an ethylene copolymer.

The ethylene copolymer in the present invention is a copolymer of ethylene and a polar monomer. As the polar monomer, one or more kinds of vinyl ester such as vinyl acetate, vinyl propionate; unsaturated carboxylic acid ester such as methyl acrylate, ethyl acrylate, isopropyl acrylate, isobutyl acrylate, n-butyl acrylate, isooctyl acrylate, methyl methacrylate, isobutyl methacrylate, dimethyl maleate; unsaturated carboxylic acid such as acrylic acid, methacrylic acid, fumaric acid, itaconic acid, monomethyl maleate, monoethyl maleate, maleic anhydride, itaconic anhydride; salts of these unsaturated carboxylic acids; carbon monoxide; sulfur dioxide; and the like, can be exemplified. As the unsaturated carboxylic acid salt, salt of a monovalent metal such as lithium, sodium, potassium; a polyvalent metal such as magnesium, calcium, zinc can be exemplified.

As a preferable specific example of the ethylene copolymer, ethylene-vinyl ester copolymer such as ethylene-vinyl acetate copolymer; ethylene-unsaturated carboxylic acid ester copolymer such as ethylene-methyl acrylate copolymer, ethylene-ethyl acrylate copolymer, ethylene-methyl methacrylate copolymer, ethylene-isobutyl acrylate copolymer, and ethylene-n-butyl acrylate copolymer; ethylene-unsaturated carboxylic acid copolymer and ionomer thereof such as ethylene-acrylic acid copolymer, ethylene-methacrylic acid copolymer, and ethylene-isobutyl acrylate-methacrylic acid copolymer; and the like, can be exemplified. Among them, ethylene-vinyl acetate copolymer or ethylene-(meth)acrylate ester is particularly preferable.

Content of the polar monomer in the ethylene copolymer to be used in the present invention varies depending on kind thereof, but in view of transparency, heat resistance, adhesive property, flexibility, moldability, durability, insulating property, and the like, for example, for the case of ethylene-vinyl acetate copolymer and ethylene-unsaturated carboxylic acid ester copolymer, polar monomer content is 10 to 40% by weight, and preferably 15 to 30% by weight; for the case of ethylene-unsaturated carboxylic acid copolymer or ionomer thereof, ethylene content is 65 to 95% by weight, and preferably 70 to 90% by weight, unsaturated carboxylic acid content is 2 to 20% by weight, and preferably 5 to 20% by weight, and degree of neutralization is 90% or less, and preferably 80% or less.

As such ethylene copolymer, in view of molding processability, mechanical strength, and the like, the one having a melt flow rate measured at 190° C. under 2,160 g of load according to JIS K7210-1999 (MFR, hereinafter, same as above) of 1 to 100 g/10 minutes, particularly 5 to 50 g/10 minutes is preferably used. These ethylene-vinyl acetate copolymer, ethylene-unsaturated carboxylic acid ester copolymer and ethylene-unsaturated carboxylic acid copolymer can be obtained by a radical copolymerization at high temperature under high pressure. Also, the ionomer of ethylene-unsaturated carboxylic acid copolymer can be obtained by reacting an ethylene-unsaturated carboxylic acid copolymer with a metal compound.

In the dialkoxysilane having a double bond to be compounded in the crosslinkable ethylene copolymer composition of the present invention, the group having a double bond can include acryloxy group, methacryloxy group (both are collectively referred to as (meth)acryloxy group), vinyl group, p-styryl group, and the like. (Meth)acyloxy group is more preferably contained as 3-(meth)acryloxypropyl group. Preferable example of such dialkoxysilane having a double bond can include dialkoxysilane containing 3-(meth)acryloxypropyl group such as 3-methacryloxypropylmethyl-dimethoxysilane, 3-methacryloxypropylmethyl-diethoxysilane, 3-acryloxypropylmethyl-dimethoxysilane, 3-acryloxypropylmethyl-diethoxysilane; vinyl group-containing dialkoxysilane such as vinylmethyl-dimethoxysilane, vinylmethyl-diethoxysilane; p-styryl group-containing dialkoxysilane such as p-styrylmethyl-dimethoxysilane, p-styrylmethyl-diethoxysilane. Among them, 3-(meth)acryloxypropyl group-containing dialkoxysilane is preferable, and 3 -methacryloxypropylmethyl-dimethoxysilane and 3-methacryloxypropylmethyl-diethoxysilane are particularly preferable.

When trialkoxysilane is used in the crosslinkable ethylene copolymer composition, adhesive property of said ethylene copolymer composition or a sheet composed of said composition commences to decrease from a comparatively earlier stage. Contrary, when the dialkoxysilane having a double bond of the present invention is used, the adhesive property of ethylene copolymer composition or a sheet composed of said composition can be maintained for a longer period.

The dialkoxysilane having a double bond is compounded in an amount of 3 parts by weight or less, preferably 0.3 to 3 parts by weight, and particularly preferably 0.05 to 1.5 parts by weight to 100 parts by weight of the ethylene copolymer, from the viewpoints of adhesive property improvement effect and insulation resistance as well as from the viewpoint of sustainable adhesive property.

That is, by compounding the dialkoxysilane having a double bond in the above ratio, the crosslinkable ethylene copolymer composition having superior adhesive property improvement effect and superior sustainable adhesive property, and the crosslinkable sheet composed of said composition, can be obtained.

In the encapsulating material for solar cell composed of the above-described crosslinkable ethylene copolymer composition of the present invention, in a state in which the material is incorporated in a solar cell module, it is preferable that said crosslinkable ethylene copolymer composition is crosslinked. By this state, heat resistance such as prevention of melt flow during use at high temperature can be provided while transparency is maintained. To that end, a crosslinking agent or a crosslinking agent and a crosslinking auxiliary agent are preferably compounded in the above-described crosslinkable ethylene copolymer composition.

As the crosslinking agent, in view of productivity of the solar cell module, a peroxide having a decomposition temperature (one-hour half-life temperature) of 140° C. or lower is preferable.

Such peroxide includes, for example, t-butylperoxyisopropyl carbonate, t-butyoperoxy-2-ethylhexylisopropyl carbonate, t-butyl peroxyacetate, t-butyl peroxybenzoate, t-butyl cumylperoxide, dicumyl peroxide, 2,5-dimethyl-2,5-bis(t-butylperoxy)hexane, di-t-butyl peroxide, 1,3-bis(2-t-butylperoxyisopropyl)benzene, 2,5-dimethyl-2,5-bis(benzoylperoxy)hexane, 2,5-dimethyl-2,5-bis(t-butylperoxy)hexine-3, 1,1 -bis(t-butylperoxy)-3 ,3,5-trimethylcyclohexane, 1,1-bis(t-butylperoxy)cyclohexane, 1,1-bis(t-amylperoxy)cyclohexane, 2,2-bis(t-butylperoxy)butane, methyl ethyl ketone peroxide, 2,5-dimethylhexyl-2,5-bisperoxybenzoate, t-butyl hydroperoxide, p-menthane hydroperoxide, benzoyl peroxide, p-chlorbenzoyl peroxide, t-butyl peroxyisobutylate, n-butyl-4,4-bis(t-butylperoxy)valerate, ethyl-3,3-bis(t-butylperoxy)butylate, hydroxyheptyl peroxide, dichlorohexanone peroxide, and the like. The crosslinking agent is effectively compounded in a ratio of 0.1 to 5 parts by weight, and particularly 0.5 to 3 parts by weight to 100 parts by weight of the ethylene copolymer.

Further, as a specific example of the crosslinking auxiliary agent, polyallyl compound having two or more unsaturated groups such as allyl group and (meth)acryloxy group and polyunsaturated compound such as poly(meth)acryloxy compound can be exemplified. More specifically, the crosslinking auxiliary agent can include polyallyl compound such as triallyl isocyanurate, triallyl cyanurate, diallyl phthalate, diallyl fumarate, and diallyl maleate; poly(meth)acryloxy compound such as ethylene glycol diacrylarate, ethylene glycol dimehacrylarate, and trimethylolpropane trimethacrylate; divinylbenzene; and the like. The crosslinking auxiliary agent is effectively compounded in a ratio of 5 parts by weight or less, and particularly 0.1 to 3 parts by weight to 100 parts by weight of the ethylene copolymer.

Instead of compounding peroxide as the above-described crosslinking agent, a photosensitizer may be compounded as a crosslinking agent in the above-described crosslinkable ethylene copolymer composition to perform crosslinking by light. The photosensitizer includes, for example, benzoin, benzophenone, benzoin methyl ether, benzoin ethyl ether, benzoin isopropyl ether, benzoin isobutyl ether, dibenzyl, 5-nitroacenaphthene, hexachlorocyclopentadiene, p-nitrodiphenyl, p-nitroaniline, 2,4,6-trinitroaniline, 1,2-benzanthraquinone, 3-methyl-1,3-diaza-1,9-benzanthrone, and the like. These photosensitizers are effectively compounded in a ratio of 0.1 to 5 parts by weight, and particularly 0.5 to 3 parts by weight to 100 parts by weight of the ethylene copolymer.

In addition, in order to prevent deterioration of the encapsulating material due to ultraviolet ray in the sunlight, at least one kind of weathering stabilizers such as antioxidant, light stabilizer, UV-absorbing agent is effectively compounded. As the antioxidant, for example, various kinds of hindered phenol type and phosphite type compounds can be suitably used. In addition, as the light stabilizer, those of hindered amine type can be suitably used. Further, as the UV-absorbing agent, for example, those of benzophenone type such as 2-hydroxy-4-methoxybenzophenone, 2,2′-dihydroxy-4-methoxybenzophenone, 2-hydroxy-4-methoxy-2-carboxybenzophenone, 2-hydroxy-4-n-octoxybenzophenone; benzotriazole type such as 2-(2′-hydroxy-3′,5′-di-t-burylphenyl)benzotriazole, 2-(2′-hydroxy-5-methylphenyl)benzotriazole, 2-(2′-hydroxy-5-t-octylphenyl)benzotriazole; salicylic acid ester type such as phenyl salicylate, p-octylphenyl salicylate; and the like, can be used. These weathering stabilizers are effectively compounded in a ratio of 5 parts by weight or less, and particularly 0.1 to 3 parts by weight to 100 parts by weight of the ethylene copolymer.

In the crosslinkable ethylene copolymer composition of the present invention, any other additive can be compounded within an amount not to impair the intended purpose of the composition. As such other additive, various kinds of known additives can be used. As an example of other additive, pigment, dye, smoothing agent, antiblocking agent, foaming agent, foaming aid, crosslinking agent, crosslinking auxiliary agent, inorganic filler, and the like can be exemplified.

When the crosslinkable ethylene copolymer composition is used as a encapsulating material for solar cell, for example, as a discoloration-preventing agent, a fatty acid salt of a metal such as cadmium, barium can be compounded. In addition, since transparency is not required in an encapsulating material for the lower protective material side, pigment, dye, inorganic filler, and the like can be compounded for the purposes of coloring, improvement of power generation efficiency, and the like. For example, white pigment such as titanium oxide, calcium carbonate; blue pigment such as ultramarine; black pigment such as carbon black; as well as glass beads, light diffusing agent, and the like can be exemplified. In particular, when the present invention is applied to a system in which an inorganic pigment such as titanium oxide is compounded, because the present invention is superior in an effect to prevent lowering of insulation resistance, it is preferable. A preferable amount of the inorganic pigment to be compounded is 100 parts by weight or less, preferably 0.5 to 50 parts by weight, and particularly preferably 4 to 50 parts by weight to 100 parts by weight of an ethylene-polar monomer copolymer.

The crosslinkable ethylene copolymer composition of the present invention is preferably used for encapsulating the solar cell elements. In this case, as an encapsulating material, the crosslinkable ethylene copolymer composition is generally used in a sheet-like form. Molding to an encapsulating sheet can be performed by the known methods using T-die extruder, calender molding equipment, inflation molding equipment, and the like. The encapsulating sheet can be obtained, for example, by dry-blending in advance an ethylene-polar monomer copolymer and silane coupling agent, together with additives to be used if necessary such as peroxide, crosslinking auxiliary agent, inorganic pigment, and supplying the mixture from a hopper of an extruder, and then extruding to a sheet-like form at a molding temperature at which peroxide does not practically decompose if peroxide is compounded. Of course, other compounding components can be compounded by master batches. Thickness of the sheet is not particularly specified, but usually around 0.2 to 1.2 mm.

In the state where the above-described ethylene copolymer composition of the present invention is used as an encapsulating material for solar cell elements, the ethylene copolymer in the composition has been preferably cross-linked in view of heat resistance. In this case, degree of crosslinking (gel fraction, described later) of the ethylene copolymer composition is preferably in a range of 70 to 98%, and particularly preferably in a range of 80 to 98%, considering the insulating property. The crosslinking can be performed by heating the crosslinkable ethylene copolymer compound of the present invention, for example, at around 100 to 200° C.

Using such encapsulating sheet, solar cell module can be manufactured by fixing a solar cell element with upper and lower protective materials. As such solar cell module, those of various types can be exemplified. For example, the solar cell module can include the one having a constitution in which a solar cell element is interleaved by the encapsulating materials from both sides like upper transparent protective material/encapsulating sheet/solar cell element/encapsulating sheet/lower protective material. In the solar cell module having such constitution, preferably the encapsulating material of the present invention not containing an inorganic pigment is used for the one in the upper transparent protective material side, whereas the encapsulating material of the present invention containing an inorganic pigment is used for the one in the lower protective material side. In addition, as another type of solar cell modules, the one having a constitution in which a encapsulating sheet and an upper transparent protective material are formed on a solar cell element which is formed on the inner circumference surface of a lower substrate protective material, the one having a constitution in which a encapsulating sheet and a lower protective material are formed on a solar cell element which is formed on the inner circumference surface, for example, an amorphous solar cell element made by sputtering or the like on a fluorocarbon resin-based sheet, and the like can be included.

As the solar cell element, various types of solar cell elements, for example, silicon type such as single crystal silicon, polycrystal silicon, amorphous silicon; groups or II-VI groups compounds semiconductor system such as gallium-arsenic, copper-indium-selenium, cadmium-tellurium; and the like, can be used. The encapsulating material of the present invention is useful particularly for encapsulating an amorphous solar cell element, for example, amorphous silicon.

As the upper protective material constituting the solar cell module, glass, acrylic resin, polycarbonate, polyester, fluorine-containing resin, and the like can be exemplified. In addition, as the lower protective material, single body or multilayer sheet of metal or various types of thermoplastic resin films, for example, a single layer or multilayer sheet of metal such as tin, aluminum, stainless steel; inorganic material such as glass; polyester; polyester vapor-deposited with inorganic substance, fluorine-containing resin, polyolefin, and the like, can be exemplified. The encapsulating material of the present invention shows a superior adhesive property to these upper or lower protective material.

The solar cell module can be manufactured by temporarily bonding said encapsulating sheet to a solar cell element and protective materials at a temperature at which the crosslinking agent does not substantially decompose but the encapsulating sheet of the present invention melts, then heating up to perform sufficient adhesion and crosslinking. In order to obtain a solar cell module having a superior heat resistance, the encapsulating sheet may be cross-linked so that gel fraction of the encapsulating sheet layer becomes 70 to 98%, preferably 80 to 98%. Here, the gel fraction is defined as a value obtained by dipping a sample (1 g) in xylene (100 ml), heating at 110° C. for 24 hours, filtering with a 20 mesh metal screen, and then calculating a fraction by weight of the undissolved material.

Consequently, formulation of additives for the encapsulating sheet may be selected so that these various conditions can be satisfied, for example, kinds and compounding ratios of crosslinking agent and the like may be properly selected.

Although the crosslinkable ethylene copolymer composition of the present invention is suitably used as an encapsulating material for a solar cell, the composition can be used for other uses utilizing the properties, thereof. Such other uses include use etc. as an intermediate membrane of laminated glass.

### EXAMPLE

Hereinafter, the present invention will be explained further in detail. The present invention is not limited to these Examples at all.

Raw materials and evaluation methods for physical properties used in Examples and Comparative Examples are shown below.
1. Raw materials

(1) EVA resin: ethylene-vinyl acetate copolymer (vinyl acetate content: 28% by weight, MFR: 15 g/10 minutes)

(2) Crosslinking agent: 2,5-dimethyl-2,5-bis(t-butylperoxy)hexane (one-hour half-life temperature: 140° C.)

(3) Silane coupling agent (1): 3-methacryloxypropyl-trimethoxysilane

(4) Silane coupling agent (2): 3-methacryloxypropylmethyl-dimethoxysilane
2. Substrate

(1) Blue glass: thickness: 3 mm, size: 7.5 cm×12 cm

(2) Back sheet: PET-based back sheet (produced by Toyo Aluminum K.K.)
3. Storage conditions

(1) Condition 1: 40° C.×90% RH (relative humidity), 1 week

(2) Condition 2: 40° C.×90% RH, 2 weeks

(3) Condition 3: 23° C.×50% RH, 1 month

(4) Condition 4: 23° C.×50% RH, 2 months
4. Preparation method for the sample for adhesive strength measurement

Condition: A glass, a crosslinked sheet and a back sheet were laminated so as to become a constitution of glass/crosslinked sheet/back sheet at 125° C. for 5 minutes, followed by crosslinking (curing) at 145° C. for 20 minutes in an oven to prepare a sample.

Laminator: produced by NPC, LM-50×50 S

Constitution of sample: glass/crosslinked sheet/back sheet
5. Adhesive strength measurement

Measuring conditions: Sample was cut out in 10 mm width, and an adhesive strength between the back sheet and the crosslinked sheet was measured at a cross-head speed of 50 mm/minute.

### Example 1

The above-described EVA resin (5,000 g), a crosslinking agent (60 g) and a silane coupling agent (2) (3-methacryloxypropylmethyl-dimethoxysilane) (25 g) were each weighed and mixed together. The mixture was left for all day and night to allow these agents to impregnate. The resultant impregnated pellet was kneaded and extruded using an extruder (L/D=26, full flight screws, compression ratio: 2.6) at 100° C., to form a sheet (crosslinked sheet) having a uniform thickness of 0.6 mm. After storing these crosslinked sheets (sheets before crosslinking) under the above-described conditions, adhesive strengths between crosslinked sheet/back sheet were measured using the samples prepared according to the above-described preparation method for the samples for adhesive strength measurement using these stored sheets. Results are shown in Table 1.

TABLE 1

| | | Example | Comparative |
|---|---|---|---|
| | | 1 | Example 1 |
| Adhesive | Initial value | 9.3 | 13.6 |
| strength | After 40° C. × 90% | 8.5 | 8.0 |
| (N/10 mm) | RH × 1 week | | |
| | After 40° C. × 90% | 10.1 | 4.6 |
| | RH × 2 weeks | | |
| | After 23° C. × 50% | 8.3 | 8.3 |
| | RH × 1 month | | |
| | After 23° C. × 50% | 13.9 | 5.4 |
| | RH × 2 months | | |

### INDUSTRIAL APPLICABILITY

The crosslinkable ethylene copolymer composition provided by the present invention is a crosslinkable ethylene copolymer composition characterized in that the composition is superior in transparency, heat resistance, adhesive property, flexibility, moldability, durability, and the like, as well as in insulating property, and shows less decrease in adhesive property with time.

According the present invention, a crosslinkable ethylene copolymer composition for encapsulating the solar cell composed of a crosslinkable ethylene copolymer composition having superior performances is provided.

By the crosslinkable ethylene copolymer composition of the present invention, a crosslinked sheet of crosslinkable ethylene copolymer composition having superior performances, an encapsulating sheet for solar cell as well as a solar cell module using the same are provided.

Although the crosslinkable ethylene copolymer composition of the present invention is suitably used as an encapsulating material for solar cell, spreading to other uses such as use as an intermediate membrane of laminated glass and the like utilizing the properties thereof can be expected.

1. A crosslinkable ethylene copolymer composition for encapsulating solar cell element which comprises a dialkoxysilane containing 3-(meth)acryloxypropyl group in a ratio of 3 parts by weight or less to 100 parts by weight of ethylene copolymer.

2. The crosslinkable ethylene copolymer composition for encapsulating solar cell element according to claim 1, wherein the ethylene copolymer is at least one kind selected from ethylene-vinyl acetate copolymer, ethylene-unsaturated carboxylic acid ester copolymer, ethylene-unsaturated carboxylic acid copolymer, and ethylene-unsaturated carboxylic acid copolymer ionomer.

3. The crosslinkable ethylene copolymer composition for encapsulating solar cell element according to claim 2, wherein the ethylene copolymer is an ethylene-vinyl acetate copolymer containing 10 to 40% by weight of vinyl acetate.

4. (canceled)

5. The crosslinkable ethylene copolymer composition for encapsulating solar cell element according to claim 1, wherein the composition is compounded with a peroxide having one-hour half-life temperature of 140° C. or lower.

6. The crosslinkable ethylene copolymer composition for encapsulating solar cell element according to claim 1, wherein the composition is further compounded with a crosslinking auxiliary agent containing an allyl group.

7. The crosslinkable ethylene copolymer composition for encapsulating solar cell element according to claim 6, wherein the crosslinking auxiliary agent is triallylisocyanurate or triallylcyanurate.

8. The crosslinkable ethylene copolymer composition for encapsulating solar cell element according to claim 1, wherein the composition is further compounded with a weathering stabilizer additive selected from UV-absorbing agent, light stabilizer, and antioxidant.

9. (canceled)

10. (canceled)

11. A crosslinkable sheet for encapsulating solar cell element comprising the crosslinkable ethylene copolymer composition for encapsulating solar cell element according to claim 1.

12. A sheet for encapsulating solar cell element obtainable by crosslinking the crosslinkable ethylene copolymer composition or the sheet according to claim 1.

13. A solar cell module using the encapsulating sheet according to claim 12.

14. A solar cell module which contains a laminate comprising the crosslinked sheet according to claim 12 and a polyester-type back sheet.

15. The crosslinkable ethylene copolymer composition for encapsulating solar cell element according to claim 2, wherein the composition is compounded with a peroxide having one-hour half-life temperature of 140° C. or lower.

16. The crosslinkable ethylene copolymer composition for encapsulating solar cell element according to claim 3, wherein the composition is compounded with a peroxide having one-hour half-life temperature of 140° C. or lower.

17. The crosslinkable ethylene copolymer composition for encapsulating solar cell element according to claim 2, wherein the composition is further compounded with a crosslinking auxiliary agent containing an allyl group.

18. The crosslinkable ethylene copolymer composition for encapsulating solar cell element according to claim 3, wherein the composition is further compounded with a crosslinking auxiliary agent containing an allyl group.

19. The crosslinkable ethylene copolymer composition for encapsulating solar cell element according to claim 5, wherein the composition is further compounded with a crosslinking auxiliary agent containing an allyl group.

20. The crosslinkable ethylene copolymer composition for encapsulating solar cell element according to claim 2, wherein the composition is further compounded with a weathering stabilizer additive selected from UV-absorbing agent, light stabilizer, and antioxidant.

21. The crosslinkable ethylene copolymer composition for encapsulating solar cell element according to claim 3, wherein the composition is further compounded with a weathering stabilizer additive selected from UV-absorbing agent, light stabilizer, and antioxidant.

22. A crosslinkable sheet for encapsulating solar cell element comprising the crosslinkable ethylene copolymer composition for encapsulating solar cell element according to claim 2.

23. A sheet for encapsulating solar cell element obtainable by crosslinking the crosslinkable ethylene copolymer composition or the sheet according to claim 2.
